(19) United States
(12) Patent Application Publication
(10) Pub. No.: US 2026/0122941 A1
(43) Pub. Date: Apr. 30, 2026

(54) GATE STACK OPTIMIZATION FOR STACKED TRANSISTORS

(71) Applicant: International Business Machines Corporation, Armonk, NY (US)

(72) Inventors: Takashi Ando, Eastchester, NY (US); Shay Reboh, Guilderland, NY (US); Paul Charles Jamison, Averill Park, NY (US); Kishwar Mashooq, Albany, NY (US); Ruilong Xie, Niskayuna, NY (US); Nirmaan Shanker, Latham, NY (US)

(21) Appl. No.: 18/931,218

(22) Filed: Oct. 30, 2024

(51) Int. Cl. H01L 29/66; H01L 21/02; H01L 27/092; H01L 29/06; H01L 29/423; H01L 29/775; H01L 29/786

(52) U.S. Cl. CPC H10D 30/014; H10D 30/43; H10D 30/6735; H10D 62/10; H10D 84/853; H10P 14/6526; H10D 30/6757; H10D 62/121

(57) ABSTRACT

A method of fabricating a semiconductor device is provided. The method includes forming a lower transistor device including a plurality of lower semiconductor layers and a lower gate stack surrounding the plurality of lower semiconductor layers. The lower gate stack includes a gradient layer on each lower semiconductor layer included in the plurality of lower semiconductor layers, and a lower interfacial layer on the gradient layer. The method further includes forming an upper transistor device on top of the lower transistor device. The upper transistor devices includes a plurality of upper semiconductor layers and an upper gate stack surrounding the plurality of upper semiconductor layers. The upper gate stack includes an upper interfacial layer on the plurality of upper semiconductor layers. A reliability anneal is performed on the upper transistor device, while the lower interfacial layer prevents regrowth of the gradient layer when performing the reliability anneal.

### BACKGROUND

The present invention generally relates to fabrication methods and resulting structures for integrated circuits (ICs), and more specifically, to fabrication methods and resulting structures configured and arranged to provide optimized gate stacks for a stacked transistor.

Integrated chips (ICs) (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to a method of fabricating a semiconductor device is provided. The method includes forming a lower transistor device including a plurality of lower semiconductor layers and a lower gate stack surrounding the plurality of lower semiconductor layers. The lower gate stack includes a gradient layer on each lower semiconductor layer included in the plurality of lower semiconductor layers, and a lower interfacial layer on the gradient layer. The method further includes forming an upper transistor device on top of the lower transistor device. The upper transistor devices includes a plurality of upper semiconductor layers and an upper gate stack surrounding the plurality of upper semiconductor layers. The upper gate stack includes an upper interfacial layer on the plurality of upper semiconductor layers. A reliability anneal is performed on the upper transistor device, where the lower interfacial layer prevents regrowth of the gradient layer when performing the reliability anneal.

According to another non-limiting embodiment, a method of fabricating a semiconductor device includes forming a lower transistor device including a plurality of lower semiconductor layers comprising a first semiconductor material, and forming a lower gate stack surrounding the plurality of lower semiconductor layers. The lower gate stack including a lower gradient layer on each lower semiconductor layer included in the plurality of lower semiconductor layers and a lower interfacial layer on the lower gradient layer. The method further includes forming an upper transistor device including a plurality of upper semiconductor layers comprising a second semiconductor material different from the first semiconductor material. The method further includes forming an upper gate stack surrounding the plurality of upper semiconductor layers. The upper gate stack includes an upper gradient layer on each upper semiconductor layer included in the plurality of upper semiconductor layers, and an upper interfacial layer on the upper gradient layer. The method further includes performing a reliability anneal on the upper transistor device. When performing the reliability anneal, the lower interfacial layer prevents regrowth of the lower gradient layer and the upper interfacial layer prevents regrowth of the upper gradient layer.

According to yet another non-limiting embodiment, a semiconductor device includes a lower transistor device and an upper an upper transistor device stacked on top of the lower transistor device. The lower transistor device includes a plurality of lower semiconductor layers, a gradient layer on each lower semiconductor layer included in the plurality of lower semiconductor layers, and a lower interfacial layer on the gradient layer. The upper transistor device includes a plurality of upper semiconductor layers, and an upper interfacial layer on each upper semiconductor layer included in the plurality of upper semiconductor layers.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A and 1B respectively depict a top view and a cross-sectional view of a portion of an integrated circuit (IC) under-fabrication after fabrication operations according to one or more embodiments;

FIG. 2 depicts the cross-sectional view of a portion of an IC under-fabrication after fabrication operations according to one or more embodiments;

FIG. 3 depicts the cross-sectional view of a portion of an IC under-fabrication after fabrication operations according to one or more embodiments;

FIG. 4 depicts the cross-sectional view of a portion of an IC under-fabrication after fabrication operations according to one or more embodiments;

FIG. 5 depicts the cross-sectional view of a portion of an IC under-fabrication after fabrication operations according to one or more embodiments;

FIG. 6 depicts the cross-sectional view of a portion of an IC under-fabrication after fabrication operations according to one or more embodiments;

FIG. 7 depicts the cross-sectional view of a portion of an IC under-fabrication after fabrication operations according to one or more embodiments;

FIG. 8 depicts the cross-sectional view of a portion of an IC under-fabrication after fabrication operations according to one or more embodiments;

FIG. 9 depicts the cross-sectional view of a portion of an IC under-fabrication after fabrication operations according to one or more embodiments;

FIG. 10 depicts the cross-sectional view of a portion of an IC under-fabrication after fabrication operations according to one or more embodiments;

FIG. 11 depicts the cross-sectional view of a portion of an IC under-fabrication after fabrication operations according to one or more embodiments;

FIG. 12 depict a top view and cross-sectional views of a portion of an IC under-fabrication after fabrication operations according to one or more embodiments;

FIG. 13 depicts the cross-sectional view of a portion of an IC under-fabrication after fabrication operations according to one or more embodiments;

FIG. 14 depicts the cross-sectional view of a portion of an IC under-fabrication after fabrication operations according to one or more embodiments; and

FIG. 15 depicts the cross-sectional view of a portion of an IC under-fabrication after fabrication operations according to one or more embodiments.

FIG. 16 depicts the cross-sectional view of a portion of an IC under-fabrication after fabrication operations according to one or more embodiments;

FIG. 17 depicts the cross-sectional view of a portion of an IC under-fabrication after fabrication operations according to one or more embodiments;

FIG. 18 depicts the cross-sectional view of a portion of an IC under-fabrication after fabrication operations according to one or more embodiments;

FIG. 19 depicts the cross-sectional view of a portion of an IC under-fabrication after fabrication operations according to one or more embodiments;

FIG. 20 depicts the cross-sectional view of a portion of an IC under-fabrication after fabrication operations according to one or more embodiments;

FIG. 21 depicts the cross-sectional view of a portion of an IC under-fabrication after fabrication operations according to one or more embodiments;

FIG. 22 depicts the cross-sectional view of a portion of an IC under-fabrication after fabrication operations according to one or more embodiments;

FIG. 23 depicts the cross-sectional view of a portion of an IC under-fabrication after fabrication operations according to one or more embodiments; and

FIG. 24 depicts the cross-sectional view of a portion of an IC under-fabrication after fabrication operations according to one or more embodiments.

FIG. 25 depicts a flowchart of a method of forming a semiconductor structure according to one or more embodiments.

FIG. 26 depicts a flowchart of a method of forming a semiconductor structure according to one or more embodiments.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets (also referred to as semiconductor nanosheets) and sacrificial nanosheets. The sacrificial nanosheets are released from the channel nanosheets before the FET device is finalized.

Another nonplanar transistor architecture is the so-called stacked field effect transistor (FET). To increase the available computing power per unit area, a stacked FET (or SFETs) a vertical stack of two (or more) FETs over a shared substrate footprint. As one non-limiting fabrication technique, two wafers are processed separately (i.e., semiconductor stacks are built on each wafer) and later joined via a wafer bonding process. In another non-limiting fabrication technique, a lower wafer is first processed to form a lower transistor device, and an upper wafer is bonded to the upper surface of the lower wafer and fabricated to form an upper transistor device. In either scenario, the resultant stacked transistor architecture offers several improvements over planar and fin-type devices, such as the ability to build complementary devices (e.g., CMOS) at a reduced footprint. Although fabrication of stacked FETs may be challenging, efforts are ongoing to design stacked FET fabrication schemes and structures that are suitable for scaled production.

The lower and upper transistor devices (e.g., lower and upper FETs) typically employ a high-k layer that surrounds the semiconductor layers forming the respective channels to form a high-k layer interface. The high-k layer is utilized to reduce gate leakage and improve electrostatic control. The high-k layer is also typically paired with one or more work function metals (WFMs) to provide a high-k metal gate (HKMG) to tune and improve threshold and reduce gate depletion. However, an overly thick high-k layer interface may reduce drive current, cause threshold voltage instability and introduce undesirable parasitic capacitance, all which reduce the performance and reliability of the transistor device.

One or more embodiments improve fabrication methods and resulting structures for a semiconductor device such as a stacked FETs, for example, by using an optimized gate stack for sequentially stacked transistors. The optimized gate stack employs an interfacial layer between the channel and the high-k layer, which prevents interfacial layer regrowth and undesirable over-thickness of the high-k layer interface when performing a subsequent reliability anneal for the upper transistor. The reliability anneal improves the reliability of the gate stack (e.g., the gate dielectric). As described herein, the reliability of the gate stack (e.g., the gate dielectric) refers to how well the gate stack (e.g., gate dielectric) can withstand prolonged electrical stress without breaking down or experiencing significant performance degradation, indicating its ability to function consistently under operating conditions over time. An increase in gate stack reliability allows for greater resistance against issues such as leakage current, charge trapping, and dielectric breakdown, which can occur when the gate stack realizes high electric fields. The formation of the lower and upper interfacial layers described herein provides a technical effect and solution of allowing either an NFET or a PFET device to be formed as the lower transistor without causing over-thickness of the lower interfacial layer. In this manner, undesirable over-thickness of the overall high-k layer can be prevented.

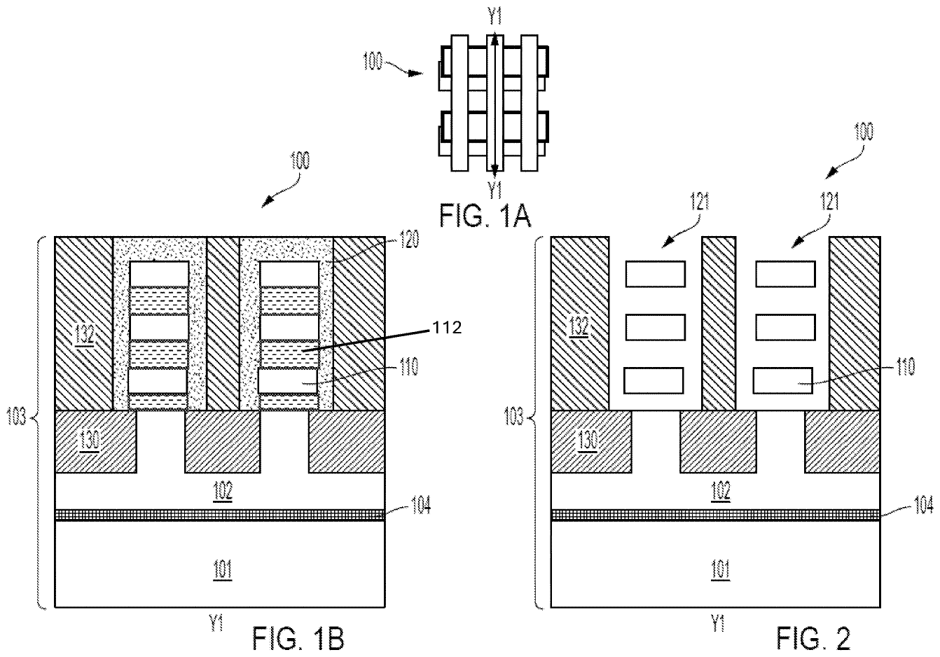

Turning now to a more detailed description of aspects of the present invention, FIG. 1A depicts a top view of a simplified illustration of a portion of an integrated circuit (IC) 100, and FIG. 1B depicts a cross-sectional view taken along line Y1 of the IC 100. For ease of understanding, some layers may be omitted from the top view so as not to obscure the figure and to view layers underneath. The top view is intended to provide a simplified illustration and a general orientation, but the top view is not intended to be a complete representation of the device. Future locations of layers may be depicted in the top view to assist the reader.

Standard semiconductor fabrication techniques can be utilized to fabricate the IC 100 as understood by one of ordinary skill in the art. For example, various suitable lithography processes including deposition techniques and etching techniques can be utilized herein. The fabrication techniques described herein can be utilized to form a stacked field effect transistor (FET) including an upper transistor device (e.g., an upper FET) stacked on a lower transistor device (e.g., a lower FET). In a non-limiting embodiment, the upper transistor device is a PFET and the lower transistor device is an NFET. In another non-limiting embodiment, the upper transistor device is an NFET and the lower transistor device is a PFET.

With continued reference to FIG. 1B, an IC 100 in an intermediate fabrication state is illustrated after performing several known fabrication processes. The intermediate state includes a first wafter that will be utilized to form a lower transistor device 103 (e.g., an NFET) of a (completed) IC 100.

The IC 100 includes a substrate 102 over a lower substrate 101 with an (intervening) etch stop layer 104 in between. The etch stop layer 104 may be formed of silicon germanium (SiGe) A stack of semiconductor layers 110 (e.g., lower semiconductor layers) and sacrificial layers 112 (e.g., lower sacrificial layers) are formed in a region above the substrate 102. The substrate 102 and lower substrate 101 are formed of silicon (Si) or other semiconductor materials.

In this example embodiment, the semiconductor layers 110 are also formed from silicon (Si) and the sacrificial layers are from SiGe. The semiconductor layers 110 will serve as the channel regions for the lower transistor device 103 of the IC 100. The semiconductor layers 110 and the sacrificial layers 112 are formed as nanosheets having a thickness ranging, for example, from about 2 nanometer (nm) to 10 nm. It should be appreciated that other ranges are possible without departing from the scope of the present disclosure.

A dummy gate 120 surrounds the semiconductor layers 110 and the sacrificial layers 112. The dummy gate 120 can be formed from any known sacrificial material (e.g., polycrystalline silicon, amorphous silicon, SiGe, etc.) that provides etch selectivity.

The IC 100 further includes shallow trench isolation (STI) regions 130 and a self-aligned gate isolation material 132. The STI regions 130 are formed in the substrate 102. Material of the STI regions 130 can include low-k dielectric materials, ultra-low-k dielectric materials, etc. The self-aligned gate isolation material 132 is disposed on the substrate 102 and may include nitride materials such as silicon nitride (SiN). The materials of the self-aligned gate isolation material 132 are intended to be different from the interlayer dielectric layer and the inner spacers for etch selectivity.

FIG. 2 depicts the IC 100 after removing the sacrificial material of the dummy gate 120 and the sacrificial layers 112. Various known etching techniques such as dry etching, for example, can be used to remove the dummy gate 120 and the sacrificial layers 112. Following removal of the dummy gate 120 and the sacrificial layers 112, openings 121 are formed around the semiconductor layers 110. The openings 121 provide access to the semiconductor layers 110 and allow for performing various gate stack optimization techniques as described herein.

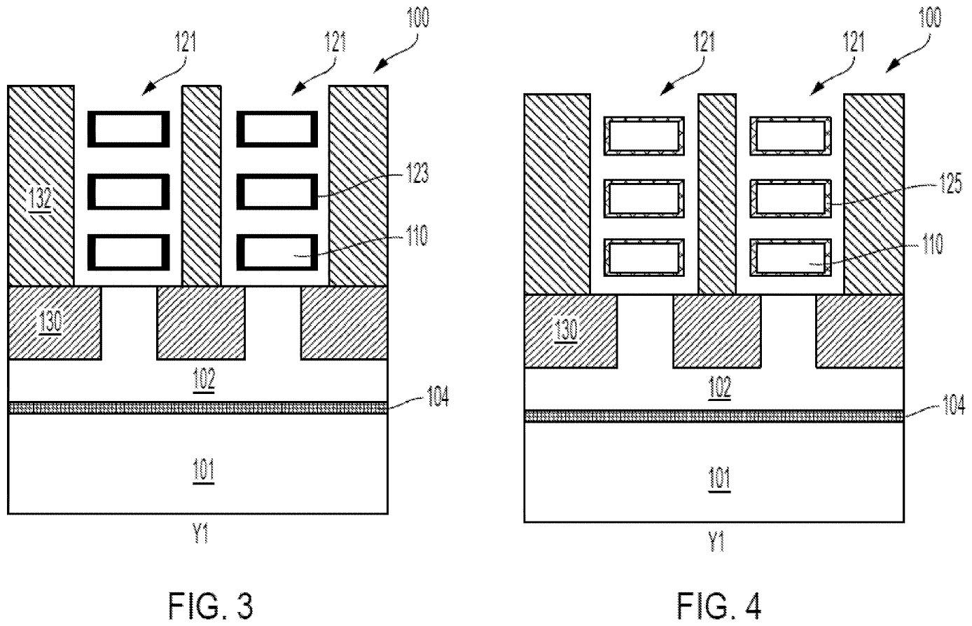

FIG. 3 depicts the IC 100 after forming a lower silicon oxide (SiO₂) layer 123 on the exposed surfaces of the semiconductor layers 110. The lower SiO₂ layer 123 can be formed using, for example, chemical oxidation, and can have a thickness ranging, for example, from about 0.5 nm to about 1.0 nm.

Turning to FIG. 4, the IC 100 is depicted after performing a nitridation process. During the nitridation process, the lower SiO₂ layer 123 is exposed to nitrogen gas, which converts the lower SiO₂ layer 123 into an interfacial layer 125. The nitridation process can be performed, for example, by performing an ammonia (NH3) anneal, a nitrogen gas (N2) plasma process, etc. In this example embodiment, the ammonia gas converts the lower SiO₂ layer 123 into silicon oxynitride (SiON), which forms the interfacial layer 125.

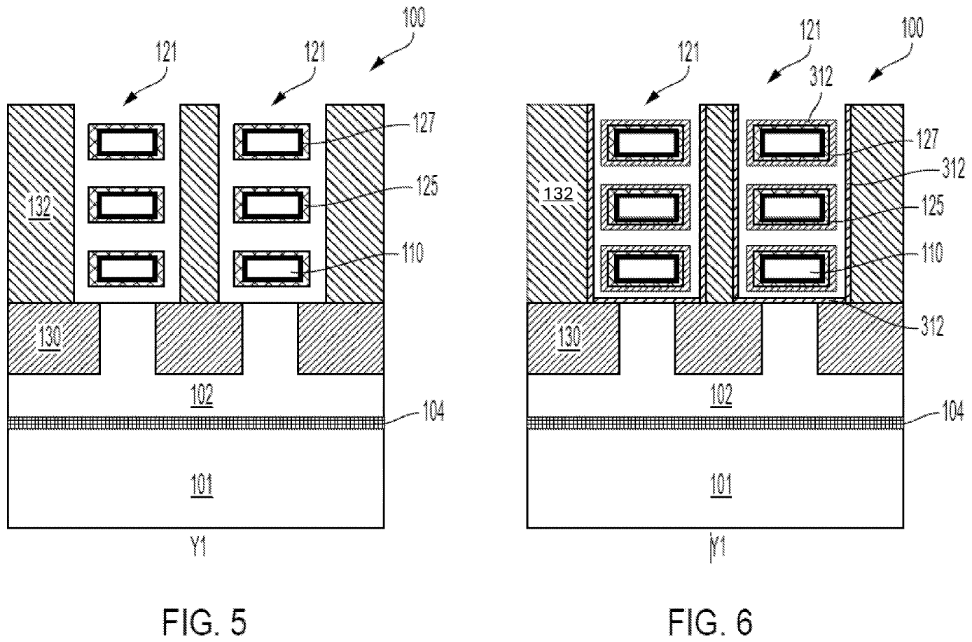

Referring to FIG. 5, the IC 100 is depicted after performing a reoxidation process. During the reoxidation process, the interfacial layer 125 is oxidized using, for example, an oxygen gas (02) anneal process. In this example embodiment where the interfacial layer 125 is formed from SiON, the reoxidation process causes the nitrogen (N) atoms incorporated during the previous nitridation process to be partially replaced by oxygen (O), thereby forming a gradient layer 127. In some embodiments the gradient layer 127 includes SiO₂ between the semiconductor layers 110 (e.g., Si channels) and the interfacial layer 125. In some non-limiting embodiments, the gradient layer 127 comprises N and SiO₂ between the semiconductor layers 110 (e.g., Si channels) and the interfacial layer 125. When the gradient layer 127 comprises N and SiO₂, a lower concentration of N is at the channel-interfacial interface (e.g., Si-IL interface), with an increasing concentration of N extending from the channel-interfacial interface to the outer surface of the interfacial layer 125. Accordingly, a low amount of SiO₂ (e.g., a thin SiO₂ layer) effectively forms the gradient layer 127 between the semiconductor layers 110 (e.g., Si channels) and the interfacial layer 125. In either scenario, the interfacial layer 125 can suppress the SiO₂ formed during the reoxidation process from further regrowth when performing a reliability anneal for the upper transistor devices (not shown in FIG. 5).

FIG. 6 depicts the IC 100 after depositing a high-k dielectric material 312. The high-k dielectric material 312 is formed on the gradient layer 127 previously formed on the semiconductor layers 110. In some embodiments, the high-k dielectric material 312 can be deposited on the sidewalls of the self-aligned gate isolation material 132 and the upper surface of the substrate 102. In one or more embodiments, examples of the high-k dielectric material 312 can include, but are not limited to, hafnium dioxide (HfO₂), zirconium dioxide (ZrO₂), aluminum oxide (AlOₓ), and lanthanum oxide (LaOₓ) and mixtures thereof.

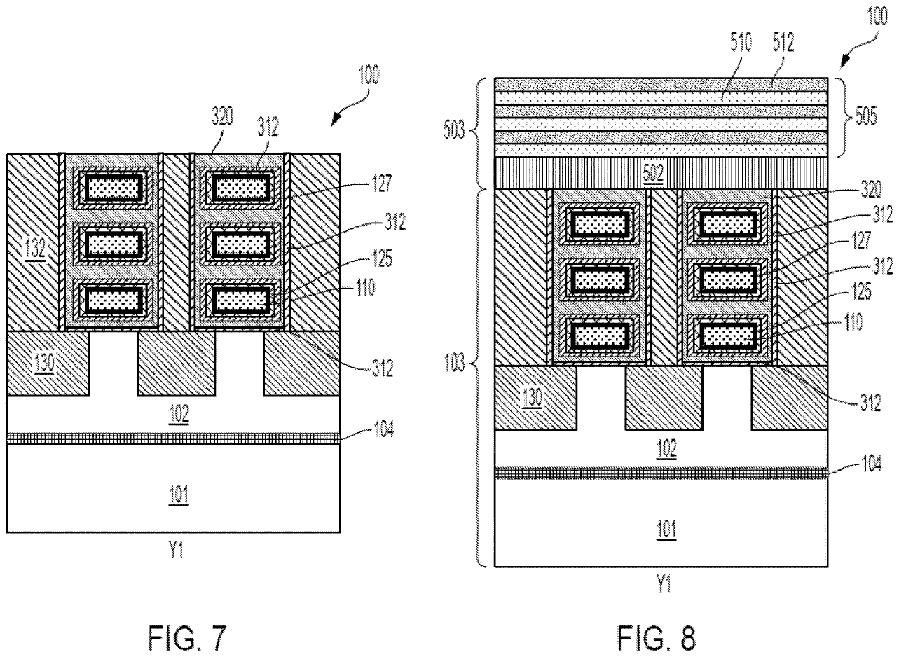

FIG. 7 depicts the IC 100 after filling the openings 121 with a work function (WFM) material 320. The WFM material 320 is formed on the high-k dielectric material 312. In one or more non-limiting embodiments, the WFM material 320 can be a stack of materials. For example, the WFM material 320 can include titanium nitride (TiN) with tungsten (W) formed/stacked on top of the TiN material. Chemical mechanical polishing/planarization (CMP) can be performed to polish away an excess material. Accordingly, the (lower) WFM material 320, the (lower) high-k dielectric material 312, the interfacial layer 125, and the gradient layer 127 define an optimized (lower) gate stack of the lower transistor device 103.

FIG. 8 depicts the IC 100 after bonding a second wafer (e.g., an upper wafer) to the lower transistor device 103. The second wafer will be utilized to form an upper transistor device 503 (e.g., a PFET) of a (completed) IC 100. The second wafer includes a nanosheet stack 505 and is bonded to the lower transistor device 103 via the bonding layer 502, which is formed on upper surfaces of the self-aligned gate isolation material 132 and the WFM material 320. The bonding layer 502 may include an oxide material, such as SiO₂ or other oxide materials.

The nanosheet stack 505 includes alternating layers of semiconductor layers 510 and sacrificial layers 512. In this example embodiment, the semiconductor layers 510 are formed from silicon germanium (SiGe) and serve as the channel regions for the upper transistor device 503. The semiconductor layers 510 are nanosheets and can have a thickness ranging from about 2-10 nm, or other ranges are possible. The sacrificial layers 512 are formed from a semiconductor material different from the material of the semiconductor layers 510 (e.g., SiGe) to allow for selective etching and removal with respect to the semiconductor layers 510. In a non-limiting embodiment, the sacrificial layers 512 are formed from silicon (Si).

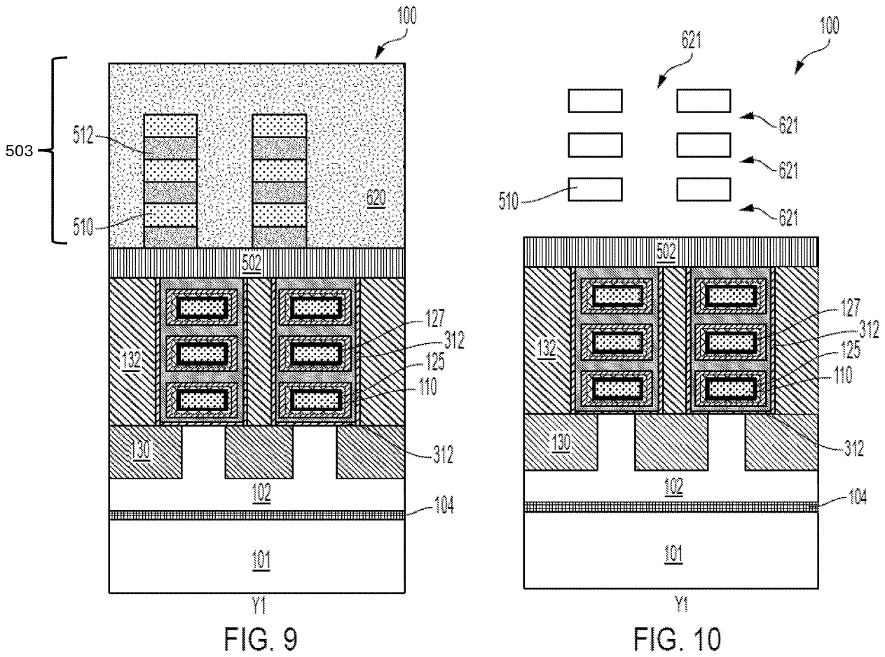

Turning to FIG. 9, the IC 100 is depicted after several fabrication processes. The fabrication processes include, but are not limited to, nanosheet stack patterning and dummy gate formation. The nanosheet stack patterning performs one or more lithography and etching processes to etch a patterned stack of sacrificial layers 512 and semiconductor layers 510 (e.g., upper semiconductor layers). The (patterned) semiconductor layers 510 will serve as channel regions for the upper transistor device 503 of the IC 100. A dummy gate formation process forms a (top) dummy gate 820 that surrounds the patterned stack of sacrificial layers 512 and semiconductor layers 510. The material of the (top) dummy gate 820 can include silicon germanium or any suitable material for selective etching.

FIG. 10 depicts the IC 100 after (top) dummy gate removal and sacrificial layer removal. According to a non-limiting embodiment, one or more etching processes are performed to remove the (top) dummy gate 820 and (patterned) sacrificial layers 512. Accordingly, openings 621 are formed which allows access to the semiconductor layers 510 to perform various gate stack optimization techniques as described herein.

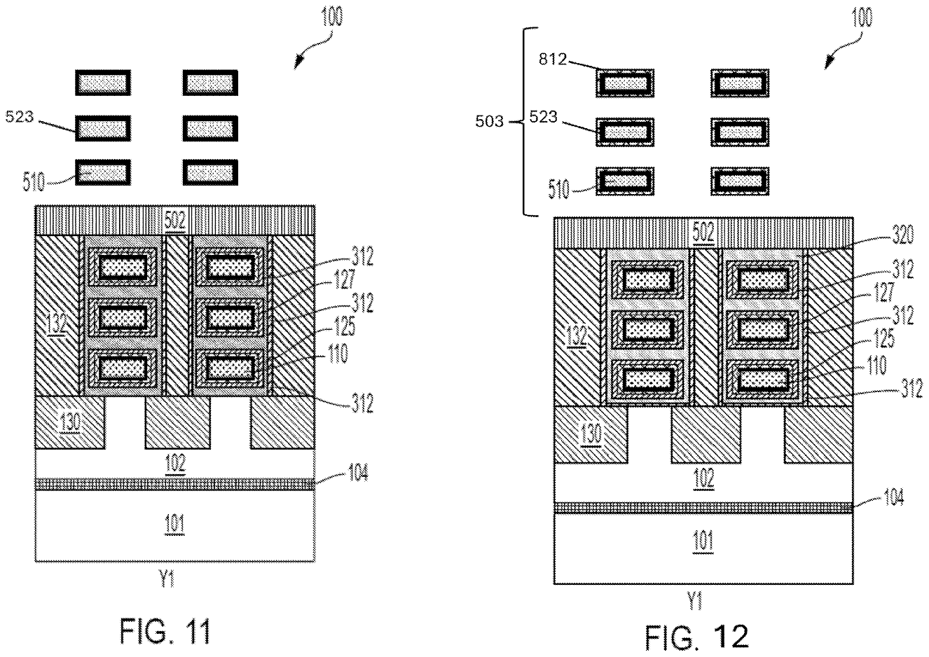

FIG. 11 depicts the IC 100 after forming an (upper) SiO₂ layer 523 on the exposed surfaces of the semiconductor layers 510. The (upper) SiO₂ layer 523 can be formed using, for example, chemical oxidation, and can have a thickness ranging, for example, from about 0.5 nm to about 1.0 nm. In this example, the (upper) SiO₂ layer 523 can serve as an interfacial layer.

FIG. 12 depicts the IC 100 after forming a high-k dielectric material 812 on the (upper) SiO₂ layer 523. As noted herein, there are many different materials that can be utilized for the high-k dielectric material 812. In one or more embodiments, examples of the high-k dielectric material 812 can include, but are not limited to, hafnium dioxide (HfO₂), zirconium dioxide (ZrO₂), aluminum oxide (AlOₓ), and lanthanum oxide (LaOₓ) and mixtures thereof. As shown in FIG. 12, the upper transistor device 503 omits the combination of a (nitridation) interfacial layer (e.g., a SiON material) and a gradient layer (e.g., SiO₂ material) between the high-k dielectric material 812 and the semiconductor layer 510. Accordingly, at least one non-limiting embodiment forms an (upper) SiO₂ layer 523 directly on the semiconductor layers 510 (e.g., the Si channels).

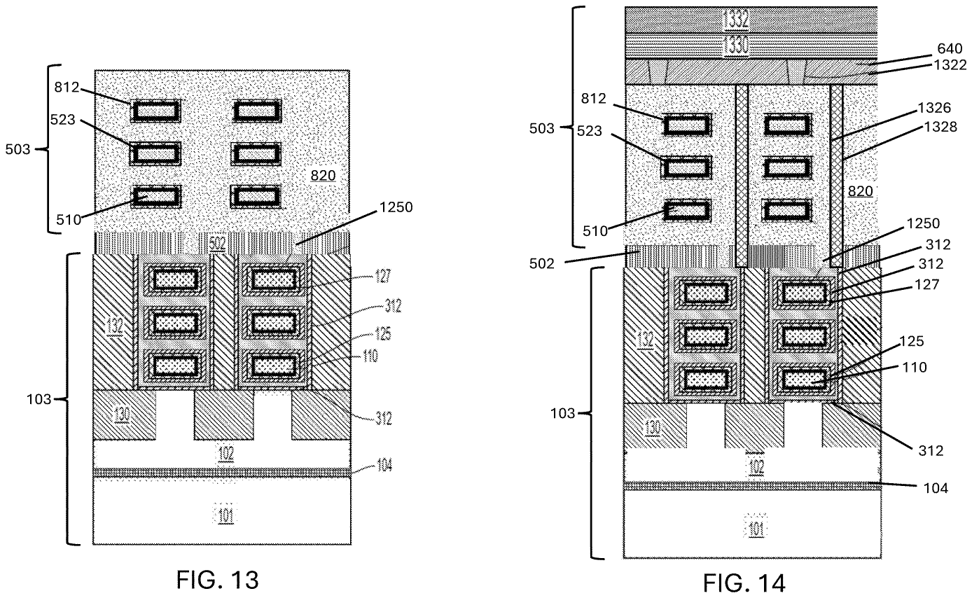

Turning now to FIG. 13, the IC 100 is depicted after performing a gate connection and filling the openings 621 with an (upper) WFM material 820 that surrounds the high-k dielectric material 812. The (upper) WFM material 820 also forms gate connectors 1250 that connect the gates of the upper transistor device and the lower transistor device. In one or more embodiments, openings (not shown) can be patterned in the bonding layer 502, and the openings are filled with the (upper) WFM material 820, thereby forming the gate connectors 1250. In one or more non-limiting embodiments, the WFM material 820 can be a stack of materials like similar to the (lower) WFM material 320. In one or more embodiments, the (upper) WFM material 820 can include TiN/W stack including a titanium nitride (TiN) material with tungsten (W) formed/stacked on top of the TiN material. Accordingly, the (upper) WFM material 820, the (upper) high-k dielectric material 812, and the (upper) SiO₂ layer 523 define an optimized (upper) gate stack of the upper transistor device 503.

After depositing the high-k dielectric material 812, a reliability anneal is performed to achieve one or more technical benefits, including improvement of the gate stack reliability (e.g., gate dielectric reliability). When performing the reliability anneal, the (lower) interfacial layer 125 prevents regrowth of the gradient layer 127. In this example, the (lower) interfacial layer 125 comprises SiON which prevents SiO₂ regrowth of the gradient layer 127. After performing the reliability anneal, the upper WFM material 820 is formed, followed by a CMP to polish away any excess material.

FIG. 14 depicts the IC 100 after forming middle-of-line (MOL) and back-of-line (BEOL) processing operations. The MOL processing operations connect the front-end-of-line (FEOL) components (e.g., transistors, FEOL interconnect layers) to BEOL metal interconnects. The MOL can involve the creation of contact structures, such as vias and contacts, that link transistors to the metal layers to provide proper electrical connectivity. According to a non-limiting embodiment, the MOL processing operations include forming frontside gate contacts 1322 that are surrounded by an ILD material 640.

The MOL processing operations also include forming vias 1326 with liners 1328, which extend through the upper transistor device 503. Example materials of the vias 1326 may include oxide materials. The liner 1328 can include nitride materials such as SiN, SiBCN, SiOCN, etc. Materials of the liner 1328 and the vias 1326 are selected to have etch selectivity with respect to each other.

The BEOL processing in semiconductor fabrication involves the steps required to create the metal interconnect layers that link transistors and other components on a chip. According to a non-limiting embodiment, the BEOL processing can be performed to form a frontside interconnect layer 1330, and a carrier wafer 1332 is bonded on the frontside interconnect layer 1330 in preparation for wafer flip. The frontside interconnect layer 1330 is electrically connected to the upper transistor device 503 by the frontside gate contacts 1322.

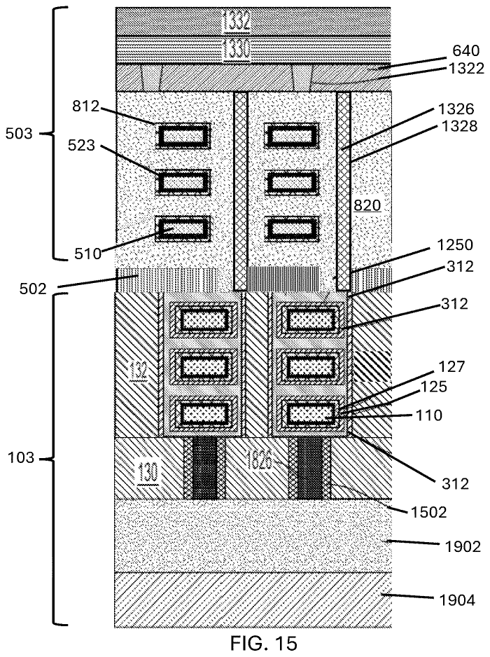

Turning to FIG. 15, a (completed) IC 100 is depicted after performing various backside fabrication processes on the backside of the IC. The backside fabrication processes include backside spacer formation, backside gate cap formation, and backside interconnect layer formation. In a non-limiting embodiment, the IC 100 can be flipped to perform the IC backside processing. However, for consistency and to assist the reader, the IC 100 is not illustrated as being flipped in the figures.

The backside spacer formation includes removing the lower substrate, the etch stop layer and the upper substrate, and forming protective spacers 1502 on sidewalls of the high-k dielectric material 312. According to a non-limiting embodiment, the protective spacers 1502 may include a nitride-based material. The nitride-base material includes, but is not limited to, SiN, SiBCN, SiOCN, SiOC, SiCN, SiO₂, etc. The backside gate cap formation forms backside gate caps 1826 on the (lower) WFM material 320. Example materials of the backside gate caps 1826 may include nitride-based materials. The backside interconnect layer formation deposits an ILD material 1902 that covers the STI regions 130 and the backside gate caps 1826, and a backside interconnect layer 1904 is formed on the ILD material 1902.

As can be seen, an upper transistor device 503 is stacked on top of the lower transistor device 103. In one or more embodiments, the lower transistor device 103 and the upper transistor device 503 can each have different threshold voltages. The lower transistor device 103 can have a super-low threshold voltage or a low threshold voltage, while the upper transistor device 503 can have a medium threshold voltage or a high threshold voltage. The upper transistor device 503 and the lower transistor device 103 can have complimentary polarities. For example, the upper transistor device 503 can be a p-type transistor (PFET) while the lower transistor device 103 can be an n-type transistor (NFET).

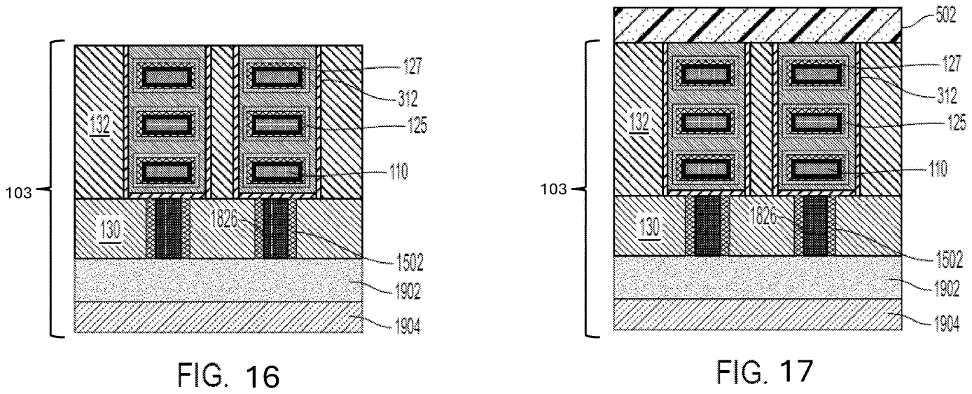

Turning now to FIG. 16, a cross-sectional view of a lower transistor device 103 of an IC 100 taken along line Y1 is illustrated in an intermediate stage of fabrication according to another non-limiting embodiment of the present disclosure. In this non-limiting embodiment, the semiconductor layers 110 are formed from silicon (Si) and will serve as the channels for either an NFET or a PFET.

Still referring to FIG. 16, the lower transistor device 103 is illustrated after performing various gate stack optimization techniques similar to those described above. For example, the gate stack optimization techniques include: a chemical oxidation process to deposit a (lower) SiO₂ layer 123 on the exposed surfaces of the semiconductor layers 110 (see FIG. 3); a nitridation operation to convert the (lower) SiO₂ layer 123 into silicon oxynitride (SiON), which forms a (lower) interfacial layer 125 (see FIG. 4); and a reoxidation process to form a (lower) gradient layer 127 between the semiconductor layers 110 and the interfacial layer 125 (see FIG. 5). A (lower) high-k dielectric material 312 is then formed around the semiconductor layers 110 (see FIG. 6) and a (lower) WFM material 320 is deposited (See FIG. 7). Accordingly, the (lower) WFM material 320, the (lower) high-k dielectric material 312, the (lower) interfacial layer 125, and the (lower) gradient layer 127 define an optimized (lower) gate stack of the lower transistor device 103. Details of the gate stack optimization techniques performed in FIG. 16 are not repeated for the sake of brevity.

Turning to FIG. 17, the lower transistor device 103 is illustrated after depositing a bonding layer 502. The bonding layer 502 may include an oxide material, such as silicon dioxide (SiO₂). Other oxide materials, however, can be utilized without departing from the scope of the present disclosure.

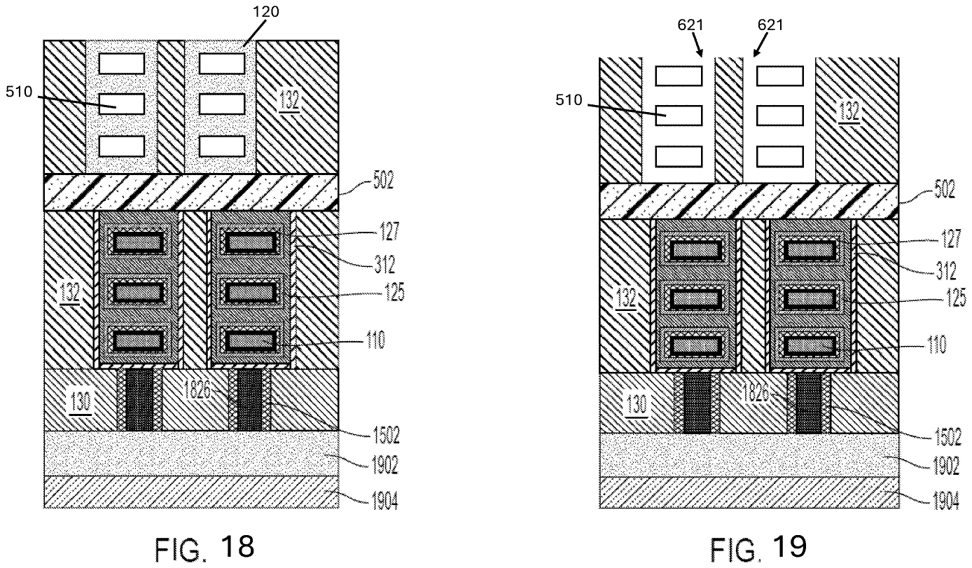

FIG. 18 depicts the IC 100 after performing several known fabrication processes to form an upper transistor device 503 on the upper surface of the bonding layer 502. According to a non-limiting embodiment, the fabrication processes used to form the lower transistor device 103 shown in FIG. 1B can also be used to form the upper transistor device 503. Therefore, details of the fabrication processes will not be repeated for the sake of brevity. In this example, the semiconductor layers 510 are formed from SiGe. Forming the semiconductor layers 510 from SiGe allows utilizing the gate stack optimization techniques described herein to form the upper transistor device 503 as either a NFET or a PFET. Accordingly, the IC 100 can be fabricated as a stacked FET having a PFET stacked on top of an NFET, can be fabricated as an NFET stacked on top of a PFET.

FIG. 19 depicts the IC 100 after removing the (upper) dummy gate 820 of the upper transistor device 503. Following removal of the (upper) dummy gate 120, openings 621 are formed around the semiconductor layers 510. The openings 621 provide access to the semiconductor layers 510 and allow for performing various gate stack optimization techniques for the upper transistor device 503 as described herein.

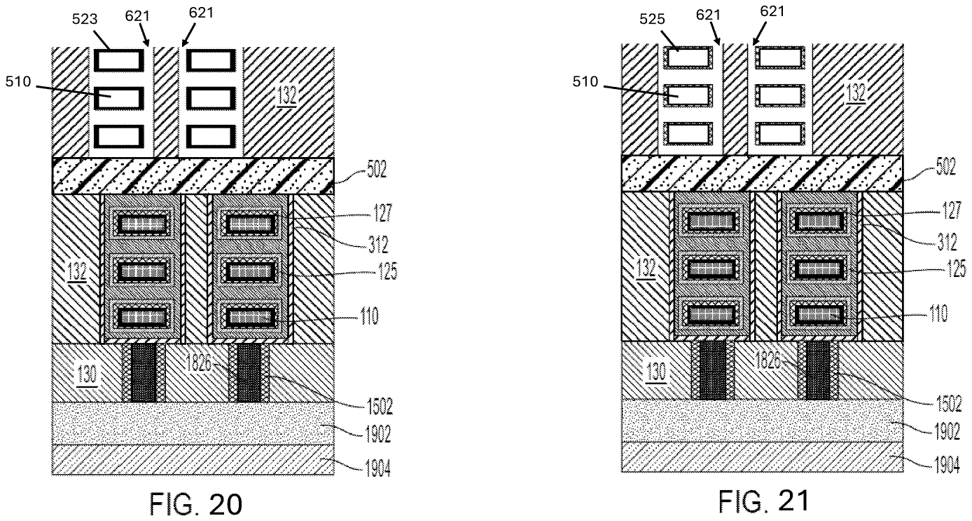

FIG. 20 depicts the IC 100 after forming an upper SiO₂ layer 523 on the exposed surfaces of the semiconductor layers 510 (e.g., SiGe channel). The upper SiO₂ layer 523 can be formed using, for example, chemical oxidation. The thickness of the SiO₂ layer 523 can have a thickness ranging, for example, from about 0.5 nm to about 1.0 nm.

Turning to FIG. 21, the IC 100 is depicted after performing a nitridation process. During the nitridation process, the (upper) SiO₂ layer 523 is exposed to nitrogen gas, which converts the (upper) SiO₂ layer 523 into an (upper) interfacial layer 525. The nitridation process can be performed, for example, by performing an ammonia (NH3) anneal, a nitrogen gas (N2) plasma process, etc. In this example embodiment, the ammonia gas converts the (upper) SiO₂ layer 523 into silicon oxynitride (SiON), which forms the (upper) interfacial layer 525.

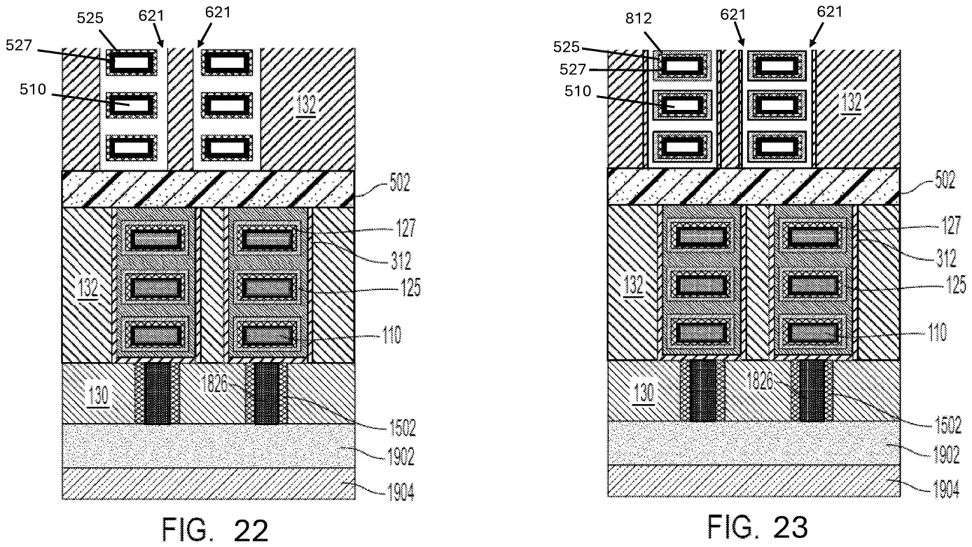

Referring to FIG. 22, the IC 100 is depicted after performing a reoxidation process. During the reoxidation process, the (upper) interfacial layer 525 is oxidized using, for example, an O2 anneal process. In this example embodiment where the (upper) interfacial layer 525 is formed from SiON, the reoxidation process causes the nitrogen (N) atoms incorporated during the previous nitridation process to be partially replaced by oxygen (O), thereby forming an (upper) gradient layer 527. In some non-limiting embodiments, the (upper) gradient layer 527 is SiO₂. In some embodiments, the (upper) gradient layer 527 comprises nitrogen (N) and SiO₂ and is formed between the semiconductor layers 510 (e.g., SiGe channel) and the interfacial layer 525. When the (upper) gradient layer 527 comprises N and SiO₂, a lower concentration of nitrogen is located at the channel-interfacial interface (e.g., SiGe-IL interface), with an increasing concentration of nitrogen (N) extending from the channel-interfacial interface to the outer surface of the (upper) interfacial layer 525. Accordingly, a low amount of SiO₂ (e.g., a thin SiO₂ layer) effectively forms the (upper) gradient layer 527 between the semiconductor layers 510 (e.g., SiGe channels) and the (upper) interfacial layer 525. In either scenario, the (upper) interfacial layer 525 can suppress the SiO₂ of the gradient (upper) layer 527 formed during the reoxidation process from further regrowth when performing a reliability anneal for the upper transistor device 503 (not shown in FIG. 22).

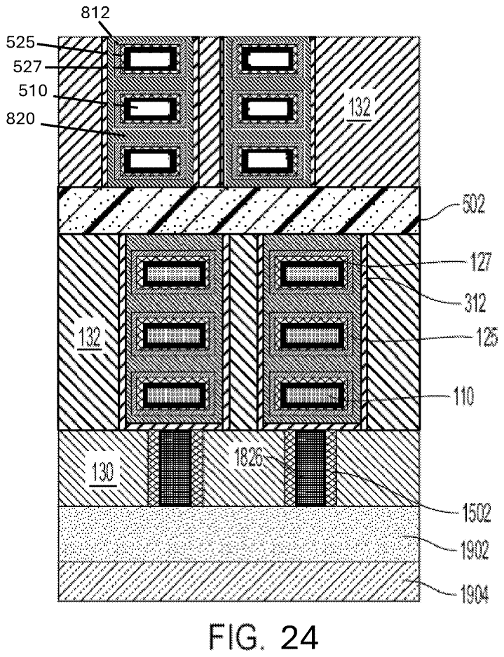

FIG. 23 depicts the IC 100 after forming an (upper) high-k dielectric material 812 on the (upper) interfacial layers 525. As noted herein, there are many different materials that can be utilized for the (upper) high-k dielectric material 812. In one or more embodiments, examples of the (upper) high-k dielectric material 812 can include, but are not limited to, hafnium dioxide (HfO₂), titanium dioxide (TiO₂), aluminum oxide (AlOₓ), and lanthanum oxide (LaOₓ).

Turning now to FIG. 24, the IC 100 is depicted after filling the openings 621 with an (upper) WFM material 820 that covers the (upper) high-k dielectric material 812 surrounding the semiconductor layers 510. In one or more non-limiting embodiments, the (upper) WFM material 820 can be a stack of materials. For example, the (upper) WFM material 820 can include TiN/W stack including a titanium nitride (TiN) material with tungsten (W) formed/stacked on top of the TiN material. Accordingly, the (upper) WFM material 820, the (upper) high-k dielectric material 812, the (upper) interfacial layer 525, and the (upper) gradient layer 527 define an optimized (upper) gate stack of the upper transistor device 503.

After depositing the high-k dielectric material 812, a reliability anneal is performed to achieve one or more technical benefits, including improving the reliability of the gate dielectric reliability. When performing the reliability anneal, the (lower) interfacial layer 125 prevents regrowth of the (lower) gradient layer 127 (e.g., the SiO₂ material), and the (upper) interfacial layer 525 prevents regrowth of the gradient (upper) layer 527 (e.g., the SiO₂ material). After performing the reliability anneal, the upper WFM material 820 is formed, followed by a CMP to polish away any excess material. Although not shown, additional MOL and/or BEOL operations can be performed. The MOL operations can form connections formed in the front-end process and the metal wiring that will be added in the BEOL operations, and the BEOL operations can deposit various metal interconnect layers onto a wafer already patterned with devices.

As can be seen, the upper transistor device 503 is stacked on top of the lower transistor device 103. In one or more embodiments, the lower transistor device 103 and the upper transistor device 503 can each have different threshold voltages. The lower transistor device 103 can have a super-low threshold voltage or a low threshold voltage, while the upper transistor device 503 can have a medium threshold voltage or a high threshold voltage. The upper transistor device 503 and the lower transistor device 103 can also have complimentary polarities. In some non-limiting embodiments, the upper transistor device 503 can be a p-type transistor (PFET) while the lower transistor device 103 can be an n-type transistor (NFET). In other non-limiting embodiment, the upper transistor device 503 can be an n-type transistor (NFET) while the lower transistor device 103 can be a p-type transistor (PFET).

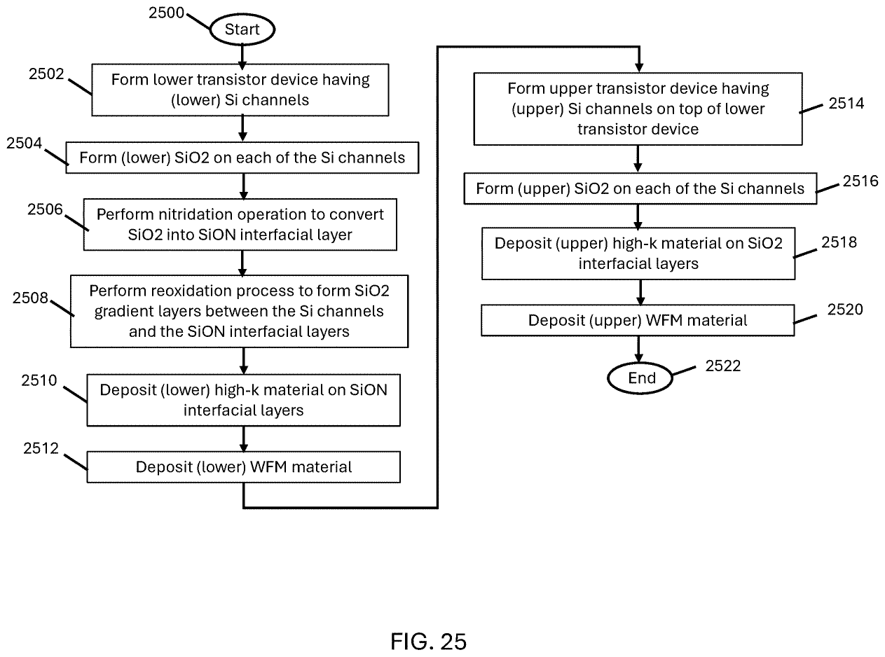

FIG. 25 illustrates a method of forming optimized gate stacks for a stacked FET according to a non-limiting embodiment of the present disclosure. The method begins at operation 2500, and a lower transistor device having (lower) Si channels is formed at operation 2502. At operation 2504, (lower) SiO₂ material is deposited on the (lower) Si channels. At operation 2506, a nitridation operation is performed to convert the (lower) SiO₂ material deposited on each of the Si channels into an SiON interfacial layer. At operation 2508, a reoxidation process is performed to form SiO₂ gradient layers between the Si channels and the SiON interfacial layers. At operation 2510, a (lower) high-k material is deposited on the SiON interfacial layers, and a (lower) WFM material is deposited to surround the (lower) high-k material at operation 2512.

Turning to operation 2514, an upper transistor device having (upper) Si channels is formed on top of the lower transistor device. At operation 2516, an (upper) SiO₂ material is deposited on the (upper) Si channels and an (upper) high-k material is deposited on the (upper) SiO₂ material at operation 2518. At operation 2520, an (upper) WFM material is deposited to surround the (upper) high-k material and the method ends at operation 2522.

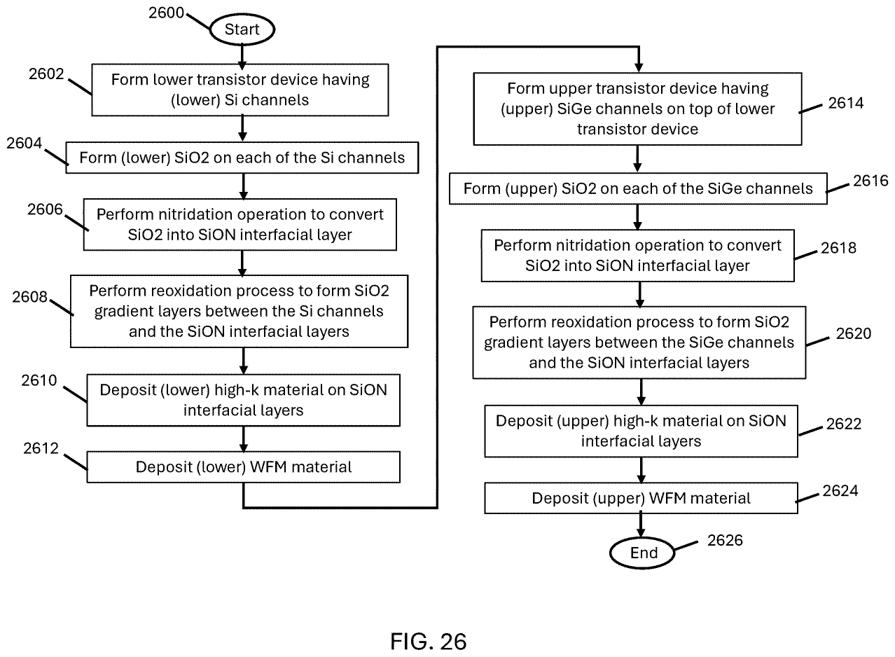

Referring now to FIG. 26, a method of forming optimized gate stacks for a stacked FET is illustrated according to another non-limiting embodiment of the present disclosure. The method begins at operation 2600, and a lower transistor device having (lower) Si channels is formed at operation 2602. At operation 2604, (lower) SiO₂ material is deposited on the (lower) Si channels. At operation 2606, a nitridation operation is performed to convert the (lower) SiO₂ material deposited on each of the Si channels into an SiON interfacial layer. At operation 2608, a reoxidation process is performed to form SiO₂ gradient layers between the Si channels and the SiON interfacial layers. At operation 2610, a (lower) high-k dielectric material is deposited on the SiON interfacial layers, and a (lower) WFM material is deposited to surround the (lower) high-k material at operation 2612.

Turning to operation 2614, an upper transistor device having (upper) SiGe channels is formed on top of the lower transistor device. At operation 2616, an (upper) SiO₂ material is deposited on the (upper) SiGe channels. At operation 2618, a nitridation operation is performed to convert the (upper) SiO₂ material deposited on each of the SiGe channels into an SiON interfacial layer. At operation 2620, a reoxidation process is performed to form SiO₂ gradient layers between the SiGe channels and the SiON interfacial layers, and an (upper) high-k material is deposited on the SiON interfacial layers at operation 2622. At operation 2624, an (upper) WFM material is deposited to surround the (upper) high-k material, and the method ends at operation 2626.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic, and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for the purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagrams or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method comprising:
forming a lower transistor device including a plurality of lower semiconductor layers and a lower gate stack surrounding the plurality of lower semiconductor layers, the lower gate stack including a gradient layer on each lower semiconductor layer included in the plurality of lower semiconductor layers, and a lower interfacial layer on the gradient layer;
forming an upper transistor device including a plurality of upper semiconductor layers and an upper gate stack surrounding the plurality of upper semiconductor layers, the upper gate stack including an upper interfacial layer on the plurality of upper semiconductor layers; and
performing a reliability anneal on the upper transistor device, wherein the lower interfacial layer prevents regrowth of the gradient layer when performing the reliability anneal.

2. The method of claim 1, wherein forming the lower gate stack comprises:
forming the plurality of lower semiconductor layers;
forming the lower interfacial layer on each lower semiconductor layer included in the plurality of lower semiconductor layers;
converting at least a portion of the lower interfacial layer into the gradient layer which is disposed between the lower interfacial layer and each lower semiconductor layer included in the plurality of semiconductor layers;
depositing a lower high-k material on the lower interfacial layer; and
depositing a lower work function metal (WFM) material that surrounds the lower high-k material.

3. The method of claim 2, wherein forming the upper gate stack comprises:
forming the plurality of upper semiconductor layers on top of the lower gate stack;
forming the upper interfacial layer on the plurality of upper semiconductor layers;
depositing an upper high-k material on the upper interfacial layer; and
depositing an upper WFM material that surrounds the upper high-k material.

4. The method of claim 1, wherein the plurality of upper semiconductor layers are formed from silicon (Si) and the plurality of lower semiconductor layers are formed from Si.

5. The method of claim 4, wherein the lower interfacial layer comprises silicon oxynitride (SiON) and the gradient layer comprises silicon oxide (SiO₂).

6. The method of claim 2, wherein forming the lower interfacial layer comprises:
forming a lower SiO₂ layer on the plurality of lower semiconductor layers; and
performing a nitridation operation that converts the lower SiO₂ layer into the lower interfacial layer comprising the SiON.

7. The method of claim 6, wherein converting the at least the portion of the lower interfacial layer into the gradient layer comprises performing a reoxidation process to convert the at least the portion of the lower interfacial layer into the gradient layer.

8. The method of claim 7, wherein the upper interfacial layer comprises SiO₂.

9. The method of claim 1, wherein the lower transistor device is an n-type field effect transistor (FET) and the upper transistor device is a p-type FET.

10. A method comprising:
forming a lower transistor device including a plurality of lower semiconductor layers comprising a first semiconductor material;
forming a lower gate stack surrounding the plurality of lower semiconductor layers, the lower gate stack including a lower gradient layer on each lower semiconductor layer included in the plurality of lower semiconductor layers and a lower interfacial layer on the lower gradient layer;
forming an upper transistor device including a plurality of upper semiconductor layers comprising a second semiconductor material different from the first semiconductor material;
forming an upper gate stack surrounding the plurality of upper semiconductor layers, the upper gate stack including an upper gradient layer on each upper semiconductor layer included in the plurality of upper semiconductor layers, and an upper interfacial layer on the upper gradient layer; and
performing a reliability anneal on the upper transistor device,
wherein when performing the reliability anneal, the lower interfacial layer prevents regrowth of the lower gradient layer and the upper interfacial layer prevents regrowth of the upper gradient layer.

11. The method of claim 10, wherein forming the lower gate stack comprises:
forming the plurality of lower semiconductor layers;
forming the lower interfacial layer on each lower semiconductor layer included in the plurality of lower semiconductor layers;
converting at least a portion of the lower interfacial layer into the lower gradient layer which is disposed between the lower interfacial layer and the plurality of lower semiconductor layers;
depositing a lower high-k material on the lower interfacial layer; and
depositing a lower work function metal (WFM) material that surrounds the lower high-k material.

12. The method of claim 11, wherein forming the upper gate stack comprises:
forming the plurality of upper semiconductor layers;
forming the upper interfacial layer on each upper semiconductor layer included in the plurality of upper semiconductor layers;
converting at least a portion of the upper interfacial layer into the upper gradient layer which is disposed between the upper interfacial layer and the plurality of upper semiconductor layers;
depositing an upper high-k material on the upper interfacial layer; and
depositing an upper WFM material that surrounds the upper high-k material.

13. The method of claim 10, wherein the plurality of upper semiconductor layers are formed from silicon germanium (SiGe) and the plurality of lower semiconductor layers are formed from silicon (Si).

14. The method of claim 13, wherein:
the lower interfacial layer comprises silicon oxynitride (SiON) and the lower gradient layer comprises silicon oxide (SiO₂); and
the upper interfacial layer comprises SiON and the upper gradient layer comprises SiO₂.

15. The method of claim 14, wherein:
forming the lower interfacial layer comprises:
forming a lower SiO₂ layer on the plurality of lower semiconductor layers; and
performing a nitridation operation that converts the lower SiO₂ layer into the lower interfacial layer comprising the SiON;
forming the upper interfacial layer comprises:
forming an upper SiO₂ layer on the plurality of upper semiconductor layers; and
performing a nitridation operation that converts the upper SiO₂ layer into the upper interfacial layer comprising the SiON.

16. The method of claim 11, wherein:
converting the at least the portion of the lower interfacial layer into the lower gradient layer comprises performing a reoxidation process to convert the at least the portion of the lower interfacial layer into the lower gradient layer; and
converting the at least the portion of the upper interfacial layer into the upper gradient layer comprises performing a reoxidation process to convert the at least the portion of the upper interfacial layer into the upper gradient layer.

17. The method of claim 10, wherein the lower transistor device is an n-type FET and the upper transistor device is a p-type FET.

18. The method of claim 10, wherein the lower transistor device is a p-type FET and the upper transistor device is an n-type FET.

19. A semiconductor device comprising:
a lower transistor device comprising:
a plurality of lower semiconductor layers;
a gradient layer on each lower semiconductor layer included in the plurality of lower semiconductor layers; and
a lower interfacial layer on the gradient layer;
an upper transistor device comprising:
a plurality of upper semiconductor layers; and
an upper interfacial layer on each upper semiconductor layer included in the plurality of upper semiconductor layers.

20. The semiconductor device of claim 19, further comprising:
a lower high-k material on the lower interfacial layer;
a lower work function metal (WFM) material surrounding the lower high-k material;
an upper high-k material on the upper interfacial layer; and
an upper WFM material surrounding the upper high-k material.
